(19) United States
(12) Patent Application Publication
(10) Pub. No.: US 2014/0153142 A1
(43) Pub. Date: Jun. 5, 2014

(54) GROUND FAULT PROTECTION

(71) Applicant: ABB Schweiz AG, Baden (CH)

(72) Inventor: Andreas CALLSEN, Brutten (CH)

(73) Assignee: ABB Schweiz AG, Baden (CH)

(21) Appl. No.: 14/092,031

(22) Filed: Nov. 27, 2013

Related U.S. Application Data
(63) Continuation of application No. PCT/EP2012/059587, filed on May 23, 2012.

(30) Foreign Application Priority Data
May 31, 2011 (EP) 11168202.7

(51) Int. Cl. G01R 31/02; H02H 3/16

(52) U.S. Cl. CPC G01R 31/025; H02H 3/16
USPC 361/42; 324/510

(57) ABSTRACT

A robust ground-fault protection system is disclosed which can possess a reduced sensitivity to system noise. In a ground-fault protection system for an electrical machine such as a generator, an injection signal with an injection frequency fᵢ is applied to the electrical machine in order to generate a periodic bias voltage on a conductor of the electrical machine, and a response signal thereto is evaluated. The injection frequency can be adapted such that a flexible approach respective of a most recent value of a system quantity of the electrical machine, can provide increased stability and reliability of the ground-fault protection system.

### RELATED APPLICATION

This application claims priority as a continuation application under 35 U.S.C. §120 to PCT/EP2012/059587, which was filed as an International Application on May 23, 2012 designating the U.S., and which claims priority to European Application 11168202.7 filed in Europe on May 31, 2011. The entire contents of these applications are hereby incorporated by reference in their entireties.

### FIELD

The disclosure relates to the field of protective relaying, and for example to earth fault protection in large electrical machines.

### BACKGROUND INFORMATION

A method for detecting ground faults on conductors of an electrical machine such as a large generator is disclosed in U.S. Pat. No. 5,739,693. Ground faults occur because of mechanical damage to the electrical insulation between conductors and iron parts on ground potential. Ground faults result in fault currents from which a fault resistance can be calculated and evaluated to assess the fault.

In order to detect a fault in the vicinity of a de-energized star point of a generator, e.g., at or near generator neutral, the conductors of the generator are biased with respect to ground potential by a suitable injection signal. Actively injecting a biasing signal results in a so-called “100% Stator Earth Protection” frequently used in Generator Protection systems.

In detail, a periodic rectangular injection signal with a fixed injection frequency equal to one quarter of the nominal network frequency (e.g., 12.5 Hz in 50 Hz grids or 15 Hz in 60 Hz grids) is injected by a dedicated signal generator through an injection transformer and the grounding resistors into the stator or rotor winding. A synchronized protection relay measures a response signal to this injection. From the response signal, a ground fault in the generator neutral or in the rotor circuit side can be calculated.

A ground fault protection system of this kind can be sensitive to disturbances which can lead to a false operation or to non-operation with adverse effects for both the operating utility and the power consumers. For example, the generator neutral (for the stator ground fault protection system) experiences, and the excitation system (for the rotor ground fault protection system) can actually generate parasitic electromagnetic signals, or noise, in certain frequency bands which might disturb the ground fault protection functions.

Likewise, existing ground fault protection systems can be sensitive to over- or under-frequency conditions. For example, in cases where the generator speed falls below 50 Hz (for example, to as little as 48.5 Hz, which is not uncommon in weak grids), rotor earth fault functions were found to trip spontaneously. For generators with static excitation the harmonics (caused by the thyristors of the excitation system) at a multiple of the generator frequency (e.g., 300 Hz when the generator runs at 50 Hz, or for example 291 Hz when the generator runs at 48.5 Hz) are eliminated by digital filters incorporated in the protection function that evaluates the response signal.

However, a nominal and static 300 Hz digital filter of the protection algorithm is less efficient for filtering 291 Hz noise. Hence, when the generator speed starts deviating from the nominal grid frequency, some noise leaks into the protection function and eventually causes a false trip.

### SUMMARY

A method is disclosed of adapting a ground-fault protection system for an electrical machine, wherein the system injects an injection signal uᵢ with an injection frequency fᵢ into a conductor of the electrical machine and evaluates a response signal u_{RE} thereto to identify a ground-fault in the electrical machine, the method comprising: measuring a system quantity of the electrical machine indicative of system noise; and adapting the injection frequency according to the system quantity.

A ground-fault protection system for an electrical machine is also disclosed, comprising: a signal generator for injecting a frequency signal uᵢ with an injection frequency fᵢ into a conductor of the electrical machine; and an earth fault protection relay for evaluating a response signal u_{RE} thereto, to identify a ground-fault in the electrical machine, wherein the signal generator is communicatively connected to the protection relay via a communication link configured for receiving a value of the injection frequency fᵢ adapted by measuring a system quantity of the electrical machine indicative of system noise; and adapting the injection frequency according to the system quantity.

### BRIEF DESCRIPTION OF THE DRAWINGS

The subject matter of the disclosure will be explained in more detail in the following text with reference to preferred exemplary embodiments which are illustrated in the attached drawings, in which:

FIG. 1 schematically shows an exemplary ground fault detection arrangement;

FIG. 2 is an exemplary measured noise spectrum between of a 60 Hz generator; and

FIG. 3 depicts two exemplary noise spectra recorded during a 50 Hz turbo-generator start-up, and an appropriately derived injection frequency

### DETAILED DESCRIPTION

Exemplary embodiments disclosed herein can provide a more robust ground-fault protection system with a reduced sensitivity to system noise. For example, a method of adapting a ground-fault protection system and a ground-fault protection system are disclosed herein

According to the disclosure, in a ground-fault protection system for an electrical machine such as a generator, an injection signal with an injection frequency fᵢ is applied to the electrical machine in order to generate a periodic bias voltage on a conductor of the electrical machine, and a response signal thereto is evaluated. The injection frequency is adapted, e.g., adjusted or selected depending on a system quantity or system property of the electrical machine that is indicative of system noise interfering with, or superposing, the response signal.

Hence, a static, predetermined choice of the injection frequency is abandoned in favour of a flexible approach respective of a most recent value of a system quantity of the electrical machine, which ultimately results in increased stability and reliability of the ground-fault protection system.

In an exemplary embodiment of the disclosure, the line or grid frequency of an electrical power grid connected to the electrical machine is a first system quantity. The injection frequency is adapted according to a deviation of an actual line frequency from the nominal line frequency of for example 50 Hz or 60 Hz. For example, the injection frequency is repeatedly adjusted proportionally to the deviation of the actual line frequency from the nominal line frequency. Accordingly, the injection frequency scales with the noise spectrum, and any parasitic noise that can escape the nominal and static digital filters of the protection function has less potential to interfere with the response signal.

In an exemplary embodiment of the disclosure, a noise spectrum n(f) reporting system noise superposing the response signal is a second system quantity. A frequency range including or covering a plurality of candidate injection frequencies is scanned for system noise, and a base injection frequency with lowest noise is selected from among the candidate frequencies. Hence, base system noise at the injection frequency can be minimised.

In an exemplary embodiment of the disclosure, a generator speed threshold nₜ separating two distinct noise regimes is a third system quantity. Two system noise spectra are measured or recorded during generator start-up as a function of generator speed, from zero to about nominal generator speed, representing system noise around a first and second candidate injection frequency. If a generator speed threshold can be identified below which a first noise spectrum is uncritical and above which the second noise spectrum is uncritical, the injection frequency during any future generator start-up can be made to change from the first to the second candidate frequency at the threshold. Hence, earth fault protection can be provided right from generator speed zero.

According to an exemplary embodiment, injection frequency adaptation allows to choose different frequencies within the possible frequency bands for different electrical machines. Hence, interference present in existing protection schemes with static injection for generators connected solidly in parallel on the same busbar, e.g., devoid of any galvanic separation, can be avoided. For dynamically adaptive injection frequencies communication between the relays provides every relay the current frequency setting of the other devices, so that a proper calibration without mutual disturbance can be achieved. A coordination scheme can assure that several relays do not start adapting at the same time which could lead to an unstable situation.

The disclosure can, for example, be beneficially applied to provide 100% Stator Earth Fault Protection in generators with a rated power as low as, for example, 20 MVA. In other words, generators with a rated power below for example 100 MVA that hitherto were limited to 95% Stator Earth Fault Protection for cost reasons can benefit from 100% Stator Earth Fault Protection without any additional measures or investments for reliability reasons.

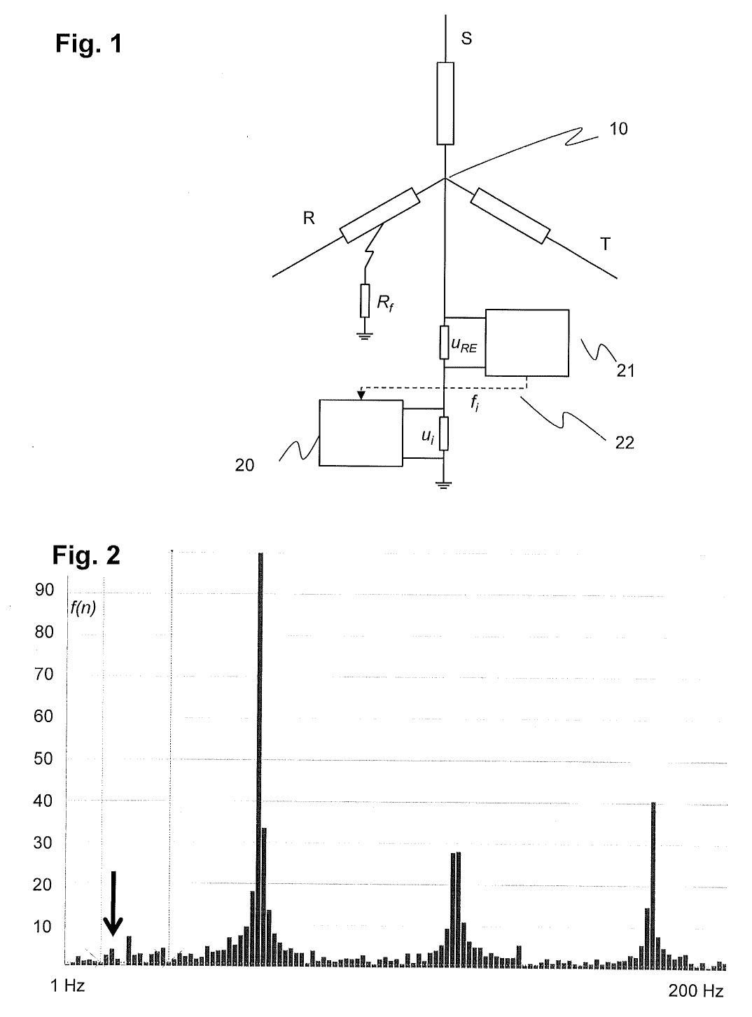

FIG. 1 depicts an exemplary circuit arrangement for detecting ground faults on the stator windings (R, S, T) of an electrical machine, for example a three-phase machine such as a generator. The star point of the winding, or generator neutral 10, is biased by means for generating an injection signal uᵢ (e.g., generated in a signal generator 20) which is fed to the star point via grounding resistances. In order to detect ground faults, a voltage u_{RE} across a grounding resistance can be measured and fed to an evaluation unit in an earth fault protection relay 21. A fault resistance R_{f} is calculated in the evaluation unit based on the injected and measured voltages. An adapted injection frequency fᵢ is determined at the protection relay according to the options noted below, and communicated from the protection relay 21 to the signal generator 20 via communication link 22.

FIG. 2 is an exemplary measured noise spectrum n(f) between 1 Hz and 200 Hz of a 60 Hz generator neutral. The noise spectrum can be established by a configuration tool that measures all relevant frequencies entering an earth fault protection relay.

To this end, a configuration tool is connected to a conductor of the generator at or near the same location as the protection relay. The protection relay can itself be adapted to execute these configuration tasks. At a rather late stage during commissioning and with potential noise sources in operation, the configuration tool scans the relevant frequencies and records the noise spectrum. In this context, noise is not only generated by the grid or the attached primary equipment such as a Start-up Frequency Converter SFC, but also caused by measurement transformers which distort a response signal.

In FIG. 2, distinctive noise peaks are visible at 60, 120 and 180 Hz. At around the known injection frequency of 15 Hz (arrow), some parasitic noise is also visible. Accordingly, candidate injection frequencies around 12 Hz or 18 Hz are better suited.

The configuration tool can determine, or suggest, one or several undisturbed frequency bands out of which a base, or nominal, injection frequency can be selected. With this, the commissioning engineer has a good guideline to select the optimal base injection frequency for the stator and rotor circuit, enabling the injection system to operate in an undisturbed frequency range with no or only little noise.

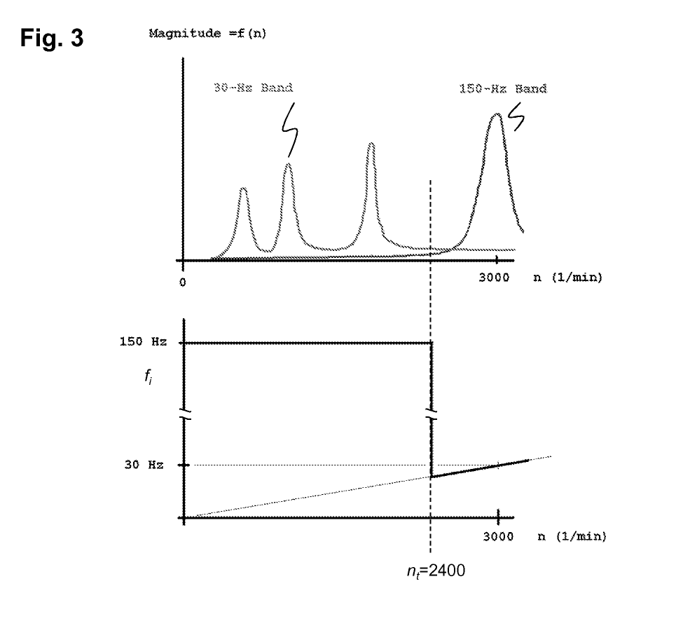

FIG. 3, top graph, depicts an exemplary noise spectrum recorded during a 50 Hz turbo-generator start-up between 1 and 3300 rpm. In the 30 Hz band, harmonics develop at 600 rpm, 900 rpm and 1800 rpm; in the 150 Hz band, harmonics only show up at 3000 rpm, i.e. at or near the nominal grid frequency.

FIG. 3, bottom graph, depicts a step-wise injection frequency fᵢ adapted to the above noise spectra, and to which the digital filtering functions of the protection relay are made to correspond.

In the beginning of the generator start-up process, the injection frequency is set to 150 Hz because no 150 Hz harmonics up to a threshold speed of 2400 rpm are expected, and afterwards, e.g., at a generator speed in excess of 2400 rpm, the injection frequency is reduced to, for example, a base injection frequency of about 30 Hz, because the 30 Hz harmonics will have been gone at this level of speed.

In order to determine an appropriate threshold or switchover generator speed, a frequency selective noise spectrum as in FIG. 3 should be recorded at least during the very first start-up process. Subsequently, such a spectrum can be updated repeatedly. Again, this can be performed by a dedicated configuration tool or by the protection relay itself. At least for all subsequent start-up processes, a working ground fault protection can then be established right from generator speed zero.

In order to mitigate filter errors in for example, under-frequency conditions, grid frequency tracking is enabled, and an actual injection frequency fᵢ is made to deviate from the base injection frequency previously chosen. This is depicted in the exemplary FIG. 3, bottom graph, by the finite slope after the discontinuous drop from the initial 150 Hz injection frequency. Contrary to the static base injection frequency of 30 Hz, the actual injection frequency fᵢ is varying proportional to the grid frequency or generator speed, and is only equal to the base injection frequency in case of 50 Hz sharp.

By way of example, a grid frequency of 48.5 Hz will lead to a deviation in the injection frequency of 0.9 Hz. Based on the assumption that the entire noise spectrum of the type depicted in FIG. 2 (including the white spots) scales with the grid frequency, parasitic noise that the static digital filters at the protection relay (which filters target strict multiples of the nominal grid frequency) are unable to block is thus circumvented. In order to arrange for the corresponding minor adaptations around the base injection frequency, the actual grid frequency is, for example, being determined by the protection relay itself.

In parallel or alternatively to the abovementioned base injection frequency adaptation by evaluating a noise profile, adaptations of the base injection frequency in relation to different generator load conditions are also possible. Such load conditions reflect different stages before and after generator load pickup; such as generator load above or below 50% of nominal load; or generator breaker closed or open. Base injection frequencies can be determined and stored in look-up tables for each identifiable load condition.

Thus, it will be appreciated by those skilled in the art that the present invention can be embodied in other specific forms without departing from the spirit or essential characteristics thereof. The presently disclosed embodiments are therefore considered in all respects to be illustrative and not restricted. The scope of the invention is indicated by the appended claims rather than the foregoing description and all changes that come within the meaning and range and equivalence thereof are intended to be embraced therein.

### LIST OF REFERENCE NUMERALS

10 generator neutral

20 signal generator

21 fault protection relay

22 communication link

What is claimed is:

1. A method of adapting a ground-fault protection system for an electrical machine, wherein the system injects an injection signal uᵢ_{_{—}} with an injection frequency fi into a conductor of the electrical machine and evaluates a response signal u_{RE} thereto to identify a ground-fault in the electrical machine, the method comprising:
measuring a system quantity of the electrical machine indicative of system noise; and
adapting the injection frequency according to the system quantity.

2. The method according to claim 1, wherein the system quantity is a line frequency fg of an electrical power grid connected to the electrical machine, the method comprising:
adapting the injection frequency fi according to a deviation of an actual line frequency from a nominal line frequency.

3. The method according to claim 1, comprising:
repeatedly adapting the injection frequency.

4. A method according to claim 2, comprising:
repeatedly adjusting the injection frequency proportionally to a deviation of the actual line frequency from the nominal line frequency.

5. The method according to claim 1, wherein the system quantity is a noise spectrum n_{(f)}, the method comprising:
measuring the noise spectrum over a frequency range including a plurality of candidate injection frequencies; and
selecting a base injection frequency with lowest noise from among the candidate injection frequencies.

6. The method according to claim 1, wherein the system quantity is a generator speed threshold nₜ the method comprising:
measuring, during generator start-up, a first system noise spectrum for a candidate start-up injection frequency and a second system noise spectrum for a candidate base injection frequency;
identifying a generator speed threshold below which the first noise spectrum is acceptable and above which the second noise spectrum is acceptable; and
selecting the injection frequency to be the start-up injection frequency below the generator speed threshold and the base injection frequency above the generator speed threshold.

7. The method according to claim 1, comprising:
recording a first noise spectrum indicative of noise in a band around a first frequency as a function of generator speed during a start-up of a generator;
recording a second noise spectrum indicative of noise in band around a second frequency as a function of generator speed during start-up the generator;
identifying a generator speed threshold nₜ below which the first noise spectrum is acceptable and above which the second noise spectrum is acceptable; and
selecting the injection frequency to be the first frequency for generator speeds below the threshold nₜ and the second frequency for generator speeds above the threshold nₜ.

8. The method according to claim 1, comprising:
selecting a first candidate injection frequency and a second candidate injection frequency;
measuring, during generator start-up, a first system noise spectrum representing system noise around the first candidate injection frequency as a function of generator speed;
measuring, during generator start-up, a second system noise spectrum representing system noise around the second candidate injection frequency as a function of generator speed;
identifying a generator speed threshold nₜ below which a first noise spectrum is uncritical and above which the second noise spectrum is uncritical; and
changing the injection frequency from the first to the second candidate frequency at the generator speed threshold nₜ during subsequent generator start-ups.

9. The method according to claim 5, wherein a further electrical machine is conductively connected to the first electrical machine, the method comprising:
selecting a further base injection frequency for the further machine that is different from the base injection frequency chosen for the electrical machine.

10. The method according to claim 1, comprising:
adapting the injection frequency in relation to different generator load conditions.

11. The method according to claim 1, wherein the ground fault protection system is configured for rotor and/or stator ground fault protection in a generator with a power in excess of 20 MVA.

12. A ground-fault protection system for an electrical machine, comprising:
a signal generator for injecting a frequency signal uᵢ with an injection frequency fᵢ into a conductor of the electrical machine; and
an earth fault protection relay for evaluating a response signal u_{RE} thereto, to identify a ground-fault in the electrical machine,
wherein the signal generator is communicatively connected to the protection relay via a communication link, and configured for receiving a value of the injection frequency fᵢ adapted to a measured system quantity of the electrical machine indicative of system noise.

13. The method according to claim 2, comprising:
repeatedly adapting the injection frequency.

14. The method according to claim 4, comprising:
recording a first noise spectrum indicative of noise in a band around a first frequency as a function of generator speed during a start-up of a generator;
recording a second noise spectrum indicative of noise in band around a second frequency as a function of generator speed during start-up the generator;
identifying a generator speed threshold nₜ below which the first noise spectrum is acceptable and above which the second noise spectrum is acceptable; and
selecting the injection frequency to be the first frequency for generator speeds below the threshold nₜ and the second frequency for generator speeds above the threshold nₜ.

15. The method according to claim 4, comprising:
selecting a first candidate injection frequency and a second candidate injection frequency;
measuring, during generator start-up, a first system noise spectrum representing system noise around the first candidate injection frequency as a function of generator speed;
measuring, during generator start-up, a second system noise spectrum representing system noise around the second candidate injection frequency as a function of generator speed;
identifying a generator speed threshold nₜ below which a first noise spectrum is uncritical and above which the second noise spectrum is uncritical; and
changing the injection frequency from the first to the second candidate frequency at the generator speed threshold nₜ during subsequent generator start-ups.

16. The method according to claim 4, wherein a further electrical machine is conductively connected to the first electrical machine, the method comprising:
selecting a further base injection frequency for the further machine that is different from the base injection frequency chosen for the electrical machine.

17. The method according to claim 10, comprising adapting the injection frequency in relation to different generator load conditions.

18. The method according to claim 11, wherein the ground fault protection system is configured for rotor and/or stator ground fault protection in a generator with a power in excess of 20 MVA.
